(19) United States
(12) Patent Application Publication
(10) Pub. No.: US 2025/0201554 A1
(43) Pub. Date: Jun. 19, 2025

(54) MULTILAYER STRUCTURE, METHOD FOR PRODUCING MULTILAYER STRUCTURE AND SEMICONDUCTOR DEVICE

(71) Applicant: Japan Display Inc., Tokyo (JP)

(72) Inventors: Hayata AOKI, Tokyo (JP); Masumi NISHIMURA, Tokyo (JP)

(73) Assignee: Japan Display Inc., Tokyo (JP)

(21) Appl. No.: 19/066,293

(22) Filed: Feb. 28, 2025

Related U.S. Application Data
(63) Continuation of application No. PCT/JP2023/030331, filed on Aug. 23, 2023.

(30) Foreign Application Priority Data
Sep. 1, 2022 (JP) 2022-139269

(51) Int. Cl. H01L 21/02; H01L 21/3065; H10D 30/47; H10D 62/10; H10D 62/85

(52) U.S. Cl. CPC H01L 21/0254; H01L 21/02428; H01L 21/02516; H10D 62/117; H10D 62/8503; H01L 21/02422; H01L 21/02631; H01L 21/3065; H10D 30/471

(57) ABSTRACT

A multilayer structure includes an amorphous substrate having an insulating surface, an orientation layer on the amorphous substrate; and a semiconductor pattern containing gallium nitride on the orientation layer, the orientation layer has a first region overlapping the semiconductor pattern and a second region not overlapping the semiconductor pattern. A top surface of the second region is positioned lower than a top surface of the first region. The orientation layer has a groove in the second region that extends from a lower end of the semiconductor pattern to the first region, and in a plan view, the groove overlaps the semiconductor pattern.

### CROSS-REFERENCE TO RELATED APPLICATIONS

This application is a Continuation of International Patent Application No. PCT/JP2023/030331, filed on Aug. 23, 2023, which claims the benefit of priority to Japanese Patent Application No. 2022-139269, filed on Sep. 1, 2022, the entire contents of each are incorporated herein by reference.

### FIELD

An embodiment of the present invention relates to a multilayer structure containing gallium nitride formed on an amorphous substrate, and a semiconductor device using the multilayer structure.

### BACKGROUND

In recent years, a semiconductor device using a semiconductor layer (hereinafter referred to as “gallium nitride-based semiconductor layer”) containing gallium nitride (GaN) has been developed. For example, a transistor element such as a HEMT (High Electron Mobility Transistor) and a light-emitting element such as an LED (Light-emitting Diode) are known as a semiconductor device using the gallium nitride-based semiconductor layer. In particular, demand for a light-emitting device using the light-emitting diode (LED) for each pixel is high, and a technique for forming a highly crystalline gallium nitride-based semiconductor layer on a substrate other than a silicon substrate has been rapidly developed. For example, Japanese laid-open patent publication No. 2018-168029 discloses a technique in which a buffer layer is formed on an insulating substrate such as a sapphire substrate or a quartz glass substrate, an insulating pattern is formed on the buffer film, and the gallium nitride-based semiconductor layer is formed on the buffer film and the insulating pattern.

### SUMMARY

A multilayer structure according to an embodiment of the present invention includes an amorphous substrate having an insulating surface, an orientation layer on the amorphous substrate, and a semiconductor pattern containing gallium nitride on the orientation layer, wherein the orientation layer has a first region overlapping the semiconductor pattern and a second region not overlapping the semiconductor pattern.

A method for producing a multilayer structure according to an embodiment of the present invention includes forming an orientation layer on an amorphous substrate having an insulating surface, depositing a semiconductor layer containing gallium nitride on the orientation layer, and etching the semiconductor layer containing gallium nitride to form a semiconductor pattern on the top surface of the orientation layer, thereby forming a first region overlapping the semiconductor pattern on the orientation layer and a second region not overlapping the semiconductor pattern on the orientation layer.

### BRIEF DESCRIPTION OF DRAWINGS

FIG. 1 is an end view showing a method for manufacturing a laminated structure according to an embodiment of the present invention.

FIG. 2 is an end view showing a method for manufacturing a laminated structure according to an embodiment of the present invention.

FIG. 3 is a plan view showing a method for manufacturing a laminated structure according to an embodiment of the present invention.

FIG. 4 is an end view showing a method for manufacturing a laminated structure according to an embodiment of the present invention.

FIG. 5 is an end view showing a method for manufacturing a laminated structure according to an embodiment of the present invention.

FIG. 6 is an end view showing a method for manufacturing a laminated structure according to an embodiment of the present invention.

FIG. 7 is an end view showing a laminated structure according to an embodiment of the present invention.

FIG. 8 is an end view showing a semiconductor device using a laminated structure according to an embodiment of the present invention.

FIG. 9 is an end view showing a semiconductor device using a laminated structure according to an embodiment of the present invention.

FIG. 10 is an end view showing a semiconductor device using a laminated structure according to an embodiment of the present invention.

### DESCRIPTION OF EMBODIMENTS

As in the above-described prior art, generally, a gallium nitride-based semiconductor layer is formed by epitaxial growth at a temperature exceeding 1000° C. using a sapphire substrate or a quartz glass substrate having a heat resistance of 1000° C. or higher. However, considering applications to a light-emitting display device, the use of an expensive sapphire substrate or quartz glass substrate is problematic in that it hinders the increase in the area of a display screen. In addition, in the processing at a temperature exceeding 1000° C., it takes time to raise the temperature at the start of the processing and to lower the temperature at the end of the processing, and the throughput decreases.

An embodiment of the present invention uses a highly crystalline gallium nitride-based semiconductor layer on an inexpensive amorphous substrate to form a laminated structure.

Hereinafter, embodiments of the present invention will be described with reference to the drawings and the like. However, the present invention can be implemented in various forms without departing from the gist thereof. The present invention is not to be construed as being limited to the description of the embodiments exemplified below. In the drawings, the widths, thicknesses, shapes, and the like of the respective portions may be schematically represented in comparison with actual embodiments for clarity of explanation. However, the drawings are merely examples, and do not limit the interpretation of the present invention.

In describing an embodiment of the present invention, a direction from a substrate toward a semiconductor layer is referred to as “on”, and a reverse direction thereof is referred to as “under”. However, the expression “on” or “under” merely describes the vertical relationship of each element. In addition, the expression “on” or “under” includes not only the case where a third element is interposed between a first element and a second element, but also the case where the third element is not interposed. Furthermore, the terms “on” or “under” include not only the case where the elements overlap in a plan view, but also the case where they do not overlap.

In describing the embodiments of the present invention, elements having the same functions as those described above may be denoted by the same reference signs or the same reference signs plus letters or other symbols, and descriptions thereof may be omitted. In addition, in the case where a part of an element needs to be described separately, a symbol such as a letter may be attached to a symbol indicating the element to distinguish the element. However, when it is not necessary to distinguish each part of the element, the description will be made using only the reference signs indicating the element.

In describing embodiments of the present invention, expressions such as “α includes A, B, or C,” “α includes any of A, B, and C,” and “a includes one selected from a group consisting of A, B, and C” do not exclude the case where α includes a plurality of combinations of A to C unless otherwise specified. Furthermore, these expressions do not exclude the case where α includes other elements.

### First Embodiment

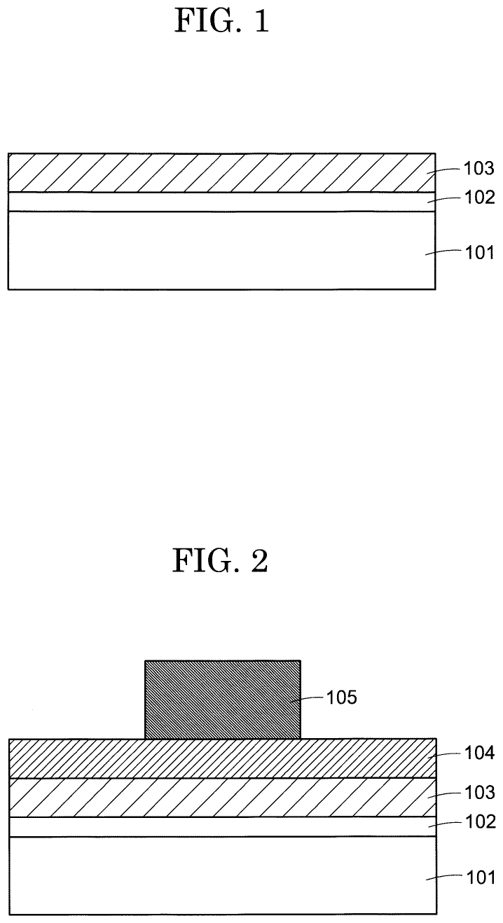

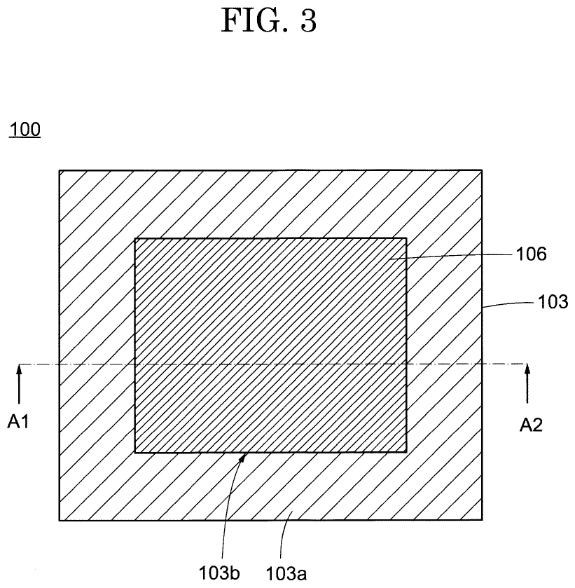

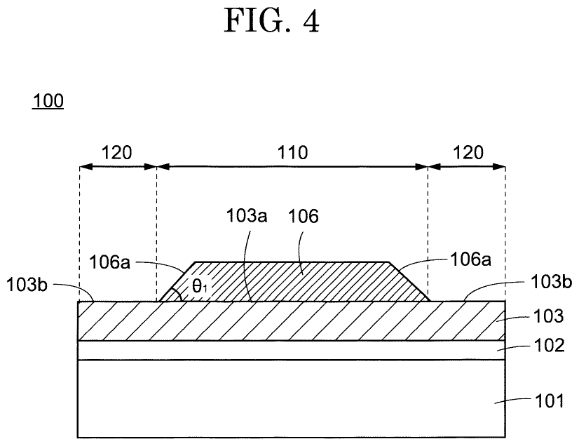

FIG. 1 and FIG. 2 are end views showing methods for manufacturing a laminated structure (also called a multilayer structure) including a semiconductor pattern containing gallium nitride according to a first embodiment. In particular, FIG. 1 and FIG. 2 show examples of forming a semiconductive pattern containing gallium nitride on the amorphous substrate. FIG. 3 is a plan view of the laminated structure, and FIG. 4 is a cross-sectional view when the laminated structure shown in FIG. 3 is cut along a line A1-A2. In addition, although FIG. 1 to FIG. 4 show an example in which a single semiconductor pattern is formed, in practice, a plurality of semiconductor patterns is formed on the substrate.

First, as shown in FIG. 1, a base layer 102 is formed on an amorphous substrate 101. For example, a glass substrate can be used as the amorphous substrate 101. The glass substrate preferably has a low content of alkaline components, a low thermal expansion coefficient, a high strain point, and a high surface flatness. For example, the content of the alkali metal (such as sodium) is 0.1% or less, the thermal expansion coefficient is lower than 50×10⁻⁷/° C., and the strain point is preferably 600° C. or higher. As will be described later, in the present embodiment, since the gallium nitride-based semiconductor layer is formed by a sputtering method, a glass substrate having lower heat resistance than that of a sapphire substrate or quartz substrate can be used. Such a glass substrate is cheaper than a sapphire substrate and a quartz substrate, and is also suitable for increasing the area of the mother glass. However, the amorphous substrate 101 of the present embodiment is not limited to the glass substrate, and may be a resin substrate such as a polyimide substrate, an acryl substrate, a siloxane substrate, or a fluororesin substrate.

For example, in the case where gallium nitride is grown on the amorphous substrate 101, such as an amorphous glass, the crystallinity of gallium nitride is affected by the surface state of the amorphous substrate 101. In particular, unevenness on the surface of the amorphous substrate 101 is a factor that generates random crystalline nuclei. As a result, crystal growth of gallium nitride occurs in a random direction, and adjacent crystals interfere with each other, thereby inhibiting crystal growth. Therefore, the base layer 102 is arranged on the amorphous substrate 101. By arranging the base layer 102, the unevenness on the surface of the amorphous substrate 101 can be relieved. The material of the base layer 102 also affects the crystallinity of the subsequently formed gallium nitride.

The base layer 102 serves as a protective layer that prevents an impurity from entering from the amorphous substrate 101. For example, the base layer 102 is composed of one or more insulating layers selected from a silicon nitride layer, a silicon oxide layer, an aluminum nitride layer, and an aluminum oxide layer. In the present embodiment, the aluminum nitride layer is used as the base layer 102. In addition, a thickness of the base layer 102 is 5 nm or more and 50 nm or less. For example, the base layer 102 is formed by the sputtering method, a CVD method, a vacuum vapor deposition method, an electron beam evaporation method, or an ALD (Atomic Layer Deposition) method or the like. In order to increase the flatness of the base layer 102, a planarization process may be performed. For example, the planarization process refers to a reverse sputtering process or an etching process.

An orientation layer 103 is formed on the base layer 102. The orientation layer 103 has the function of improving the orientation of the crystal of a semiconductor layer 104 when forming the semiconductor layer 104 containing gallium nitride (see FIG. 2), which will be described later.

The orientation layer 103 may be conductive or insulating, but preferably has crystallinity oriented along a specific axis (for example, the c-axis). The orientation layer 103 is preferably a crystal having rotational symmetry. For example, the crystal surface preferably has six-fold rotational symmetry, and preferably has a hexagonal close-packed structure, a face-centered cubic structure, or a structure equivalent thereto. In this case, the structure equivalent to the hexagonal close-packed structure or the face-centered cubic structure includes a crystal structure in which the c-axis does not form 90 degrees with respect to the a-axis and the b-axis. The orientation layer 103 having the hexagonal close-packed structure or the structure equivalent thereto is preferably oriented in the (0001) direction, that is, the c-axis direction, with respect to the amorphous substrate 101. The orientation layer 103 having the face-centered cubic structure or the structure equivalent thereto is preferably oriented in the (111) direction with respect to the amorphous substrate 101.

For example, conductive orientation layers such as titanium (Ti), titanium nitride (TiNₓ), titanium oxide (TiOₓ), graphene, zinc oxide (ZnO), magnesium diboride (MgB₂), aluminum (Al), silver (Ag), calcium (Ca), nickel (Ni), copper (Cu), strontium (Sr), rhodium (Rh), palladium (Pd), cerium (Ce), ytterbium (Yb), iridium (Ir), platinum (Pt), gold (Au), lead (Pb), actinium (Ac), thorium (Th), and the like can be used as the orientation layer 103. In particular, titanium, graphene, and zinc oxide are preferably used as orientation layer 103 having conductivity. In the present embodiment, a titanium layer is used as the orientation layer 103.

For example, insulating orientation layers such as aluminum nitride (AlN), aluminum oxide (Al₂O₃), lithium niobate (LiNbO), BiLaTiO, SrFeO, BiFeO, BaFeO, ZnFeO, PMnN-PZT, biological apatite (BAp), or the like can be used as the orientation layer 103. In particular, aluminum nitride or aluminum oxide is preferably used as the insulating orientation layer. In the present embodiment, the aluminum nitride layer is preferably used as the insulating orientation layer.

In this specification and the like, the orientation layer 103 may be a conductive orientation layer or an insulating orientation layer. In the case where there is no need to distinguish between the conductive orientation layer and the insulating orientation layer, the layer is expressed as the orientation layer 103.

The surface state of the orientation layer 103 affects the crystallinity of the semiconductor layer 104 described below. Therefore, the surface of the orientation layer 103 is preferably flat. For example, the orientation layer 103 preferably has a surface arithmetic mean roughness (Ra) of less than 2.3 nm. When the surface roughness of the orientation layer 103 is less than 2.3 nm, the semiconductor layer 104 having the c-axis orientation can be formed. Furthermore, in order to enhance the flatness of the orientation layer 103, the planarization process described in the base layer 102 may also be performed on the surface of the orientation layer 103 before forming the semiconductor layer 104.

In the present embodiment, the aluminum nitride layer is used as the base layer 102, and the titanium layer is used as the orientation layer 103. By using the aluminum nitride layer as the base layer 102, the flatness of the base layer 102 can be improved. In addition, the titanium layer is formed as the orientation layer 103 on the base layer 102 having a flat surface. As a result, the flatness of the orientation layer 103 can be improved. Therefore, it is preferable because it increases the crystallinity of the subsequently formed semiconductor layer 104.

For example, a thickness of the orientation layer 103 is 50 nm or more (preferably, 50 nm or more and 100 nm or less). The orientation layer 103 may be formed by any method. For example, the orientation layer 103 is formed by the sputtering method, the CVD method, the vacuum vapor deposition method, the electron beam evaporation method, or the ALD method.

Next, as shown in FIG. 2, the semiconductor layer 104 is formed on the orientation layer 103. In the present embodiment, gallium nitride is formed as the semiconductor layer 104 by the sputtering method. Specifically, for example, the gallium nitride is formed by the sputtering method in a state where the amorphous substrate 101 having an insulating surface (here, the amorphous substrate 101 in which the base layer 102 is arranged) is heated to 25° C. to 600° C., preferably 25° C. to 400° C. In other words, gallium nitride is formed at a temperature equal to or lower than the strain point of the amorphous substrate 101. Although gallium nitride is usually formed by a MOCVD method (Metal Organic Chemical Vapor Deposition), the MOCVD method is not appropriate in view of the heat resistance of the amorphous substrate 101 because the process temperature is high.

On the other hand, in the present embodiment, by using the sputtering method, the semiconductor layer 104 can be formed on the inexpensive amorphous substrate 101 at a lower temperature than using the MOCVD method. In addition, the semiconductor layer 104 is formed on the orientation layer 103 having crystallinity oriented along a specific axis (for example, the c-axis). Furthermore, the base layer 102 relieves the surface unevenness of the amorphous substrate 101, thereby relieving the surface unevenness of the orientation layer 103 formed on the base layer 102. As a result, the highly crystalline semiconductor layer 104 can be formed even when the semiconductor layer 104 is formed at a lower temperature than using the MOCVD method. In addition, since the amorphous substrate 101 can have a larger area than that of the sapphire substrate, it is possible to form a laminated structure 100 having a large area.

For example, the semiconductor layer 104 is formed by performing the sputtering using a sintered body of gallium nitride as a sputtering target and argon (Ar) or a mixed gas of argon (Ar) and nitrogen (N₂) as a sputtering gas. For example, a two-pole sputtering method, a magnetron sputtering method, a dual magnetron sputtering method, an opposing target sputtering method, an ion beam sputtering method, or an inductively coupled plasma (ICP) sputtering method can be applied as the sputtering method.

The conductivity type of the semiconductor layer 104 may be substantially intrinsic or may have n-type conductivity or p-type conductivity. The semiconductor layer 104 having n-type conductivity may not contain a dopant for performing valence electron control or may be doped with silicon (Si) or germanium (Ge) as an n-type dopant. The semiconductor layer 104 having p-type conductivity may be doped with one element selected from magnesium (Mg), zinc (Zn), cadmium (Cd), and beryllium (Be) as a p-type dopant. In the case where the n-type dopant is added to the semiconductor layer 104, the carrier concentration is preferably 1×10¹⁸/cm³ or more. In the case where the p-type dopant is added to the semiconductor layer 104, the carrier concentration is preferably 5×10¹⁶/cm³ or more. Furthermore, in the case where the semiconductor layer 104 is substantially intrinsic, zinc (Zn) may be contained as a dopant.

In addition, the semiconductor layer 104 may contain one or more elements selected from indium (In), aluminum (Al), and arsenic (As). A bandgap of the semiconductor layer 104 can be adjusted by these elements.

As described above, in the present embodiment, the semiconductor layer 104 containing gallium nitride is formed on the amorphous substrate 101 on which the orientation layer 103 is formed. The crystallinity of the semiconductor layer 104 formed on the orientation layer 103 is affected by the orientation axis of the orientation layer 103. For example, in the case where the orientation layer 103 has crystallinity of rotational symmetry or c-axis oriented crystallinity, the semiconductor layer 104 also has crystallinity of c-axis orientation or (111) orientation. The crystallinity of the semiconductor layer 104 is preferably monocrystalline, but may be polycrystalline, microcrystalline, or nanocrystalline. The crystal structure of the semiconductor layer 104 may have a wurtzite structure. The orientation of the semiconductor layer 104 is preferably the c-axis orientation or (111) orientation. The semiconductor layer 104 may contain an amorphous structure near the interface in contact with the orientation layer 103, but preferably has crystallinity in bulk.

A thickness of the semiconductor layer 104 is 100 nm or more and 1 μm or less. However, the thickness of the semiconductor layer 104 is not limited, and may be appropriately set according to the structure of the device. The semiconductor layer 104 may have a single-layer structure, or may be a laminated structure including a plurality of layers having different conductivity types and/or compositions.

Next, as shown in FIG. 2, a resist mask 105 is formed on the semiconductor layer 104. Next, the semiconductor layer 104 is etched using the resist mask 105 to form a semiconductor pattern 106. In the present embodiment, the semiconductor layer 104 is etched by dry etching using a halogenated gas. The halogenated gas is not particularly limited as long as it contains at least one or more halogen atoms such as a chlorine atom, a fluorine atom, and a bromine atom and is in a gaseous state at room temperature, and examples thereof include CF₄, C₂F₆, C₃F₈, C₂F₄, C₄F₈, C₄F₆, C₅F₈, CHF₃, CCl₄, CClF₃, AlF₃, AlCl₃ and the like. In addition, a plurality of halogenated gases may be mixed and used. A chlorine-based gas such as CCl₄, CClF₃, AlF₃, or AlCl₃ is preferably used as the halogenated gas. However, the present invention is not limited to this example, and the semiconductor pattern 106 may be formed using the wet etching method. As shown in FIG. 4, the semiconductor pattern 106 has a gradient (hereinafter referred to as “taper”) in which the angle of the side surface with respect to the bottom surface is θ1. Therefore, the taper angle θ1 of the semiconductor pattern 106 can be 20° or more and 50° or less (preferably, 30° or more and 40° or less). After the etching, the resist mask 105 is removed to obtain the semiconductor pattern containing gallium nitride.

As explained above, the laminated structure of the present embodiment includes the amorphous substrate 101 with the insulating surface, the orientation layer 103 formed on the amorphous substrate 101, and the semiconductor pattern 106 obtained by etching a semiconductor layer 104 containing gallium nitride formed on the orientation layer 103 by the sputtering method. In addition, by forming the semiconductor pattern 106, a first region 110 that overlaps the semiconductor pattern 106 and a second region 120 that does not overlap the semiconductor pattern 106 are formed in the orientation layer 103.

FIG. 3 is a plan view of the laminated structure 100, which has the semiconductor pattern 106 containing gallium nitride. FIG. 4 is a cross-sectional view of the laminated structure 100 cut along the A1-A2 line.

The laminated structure 100 includes the amorphous substrate 101 having an insulating surface, the orientation layer 103 on the amorphous substrate 101, and the semiconductor pattern 106 including gallium nitride on the orientation layer 103. As shown in FIG. 3 and FIG. 4, the orientation layer 103 is exposed from the semiconductor pattern 106. In other words, the orientation layer 103 has the first region 110 that overlaps the semiconductor pattern 106 and the second region 120 that does not overlap the semiconductor pattern 106. As shown in FIG. 4, a top surface 103a of the first region 110 is included in the same plane as a top surface 103b of the second region 120. The same plane allows for errors due to the processing accuracy of the orientation layer 103 and the semiconductor layer 104. Specifically, if the thickness of the orientation layer 103 in the second region 120 is larger than 90% of the thickness of the orientation layer 103 in the first region 110, the top surface 103a of the first region 110 and the top surface 103b of the second region 120 are included in the same plane. In order to process the top surface 103a of the first region 110 of the orientation layer 103 so that it is included in the same plane as the top surface 103b of the second region 120, it is preferable to etch the orientation layer 103 under conditions where the etching rate of the orientation layer 103 is lower than that of the semiconductor layer 104. The etching rate of the orientation layer 103 relative to the semiconductor layer 104 is determined by the etching conditions, such as the pressure, power, bias, gas flow ratio, temperature, and processing time of the etching device, as well as the crystallinity (film formation conditions) of the orientation layer 103. When dry etching is used, it is preferable to use chlorine-based gas and to use low power processing conditions.

In the conventional technology, an insulating layer with openings is formed on a buffer layer, and then a gallium nitride semiconductor layer is formed in the openings. Therefore, when forming a device using this gallium nitride semiconductor layer, the thickness of the gallium nitride semiconductor layer is not uniform, and the manufacturing process is increased due to the formation of the insulating layer, and it was necessary to design the device considering the shape of the insulating layer.

In contrast, according to the manufacturing method for the laminated structure 100 in an embodiment of the present invention, it is possible to continuously form the orientation layer 103 on the amorphous substrate 101 having the insulating surface and the semiconductor layer 104 having a high degree of crystallinity and a c-axis orientation on the orientation layer 103. As a result, the thickness of the semiconductor layer 104 can be formed uniformly. In addition, since there is no need to separately form an insulating layer between the orientation layer 103 and the semiconductor layer 104, the manufacturing process can be simplified. Furthermore, there is no need to design the device with the shape of the insulating layer in mind. In the present embodiment, the orientation layer 103 and the semiconductor layer 104 formed on the orientation layer 103 can be selectively etched. This makes it possible to form the laminated structure 100 with a fine semiconductor pattern 106 on the orientation layer 103. Therefore, it is possible to form a high-precision semiconductor device using the laminated structure 100.

The laminated structure 100 according to an embodiment of the present invention includes the highly crystalline semiconductor pattern 106 with the c-axis orientation. In addition, the laminated structure 100 includes the amorphous substrate 101 having an area which can be increased. Therefore, by utilizing the laminated structure 100, productivity of the LED containing gallium nitride can be increased, or a backplane in which a transistor containing gallium nitride is formed can be manufactured.

The semiconductor pattern 106 of the present embodiment has a crystalline structure that is aligned with a specific orientation axis, reflecting the orientation of the orientation layer 103. Therefore, by processing the semiconductor pattern 106 of the present embodiment and using it in a semiconductor device, it is possible to achieve a semiconductor device with excellent characteristics.

### [First Modification]

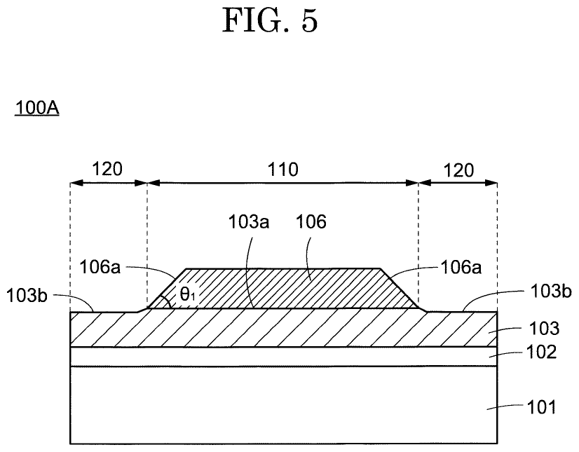

FIG. 5 is an end view of a laminated structure 100A including a semiconductor pattern containing gallium nitride in an embodiment of the present invention. The shape of the second region 120 of the orientation layer 103 of the laminated structure 100A shown in FIG. 5 is different from the shape of the second region 120 of the orientation layer 103 of the laminated structure 100.

As explained in FIG. 1 and FIG. 2, a method for manufacturing the laminated structure 100A shown in FIG. 5 also allows the continuous formation of the orientation layer 103 on the amorphous substrate 101 with an insulating surface, and the semiconductor layer 104 with a high degree of crystallinity and a c-axis orientation on the orientation layer 103. When processing the semiconductor layer 104, it is preferable to etch the semiconductor layer 104 under conditions where the etching rate of the orientation layer 103 is low, as explained in FIG. 2. When using dry etching, it is preferable to use chlorine-based gas and to use processing conditions with low power. In this case, as shown in FIG. 5, the orientation layer 103 may be over-etched with respect to the semiconductor pattern 106.

Specifically, the top surface 103b of the second region 120 of the orientation layer 103 is located lower than the top surface 103a of the first region 110. Specifically, if the thickness of the second region 120 of the orientation layer 103 is 90% or less of the thickness of the first region 110 of the orientation layer 103, then the top surface 103b of the second region 120 is located below the top surface 103a of the first region 110. In other words, the thickness of the first region 110 is larger than the thickness of the second region 120 in the orientation layer 103. In addition, the orientation layer 103 may have a side surface 103c that is continuous with the top surface 103b of the first region 110 in the second region 120.

As shown in FIG. 5, the top surface 103b of the second region 120 of the orientation layer 103 is positioned lower than the top surface 103a of the first region 110, thereby increasing the surface area of the orientation layer 103. Therefore, when forming a semiconductor device using the laminated structure 100A, the contact area with the film formed on the orientation layer 103 and the semiconductor pattern 106 can be increased. This improves the adhesion between the orientation layer 103 and the film formed on the semiconductor pattern 106. It also suppresses the occurrence of step breaks in the film formed on the orientation layer 103 and the semiconductor pattern 106.

When etching the orientation layer 103 under conditions where the etching rate is low for the semiconductor layer 104, semiconductor residue (etching residue) may occur near the lower end of the tapered portion of the semiconductor layer 104 (near the boundary between the semiconductor layer 104 and the orientation layer 103). In contrast, as shown in FIG. 5, over-etching the orientation layer 103 with respect to the semiconductor pattern 106 can suppress the occurrence of semiconductor layer residue.

### [Second Modification]

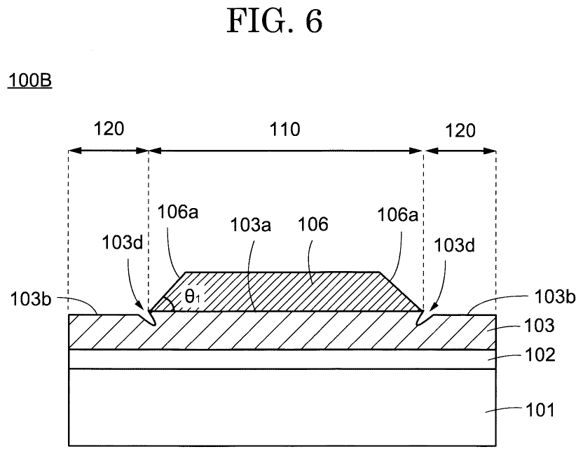

FIG. 6 is an end view of a laminated structure 100B including a semiconductor pattern containing gallium nitride in one embodiment of the present invention. The shape of the second region 120 of the orientation layer 103 of the laminated structure 100B shown in FIG. 6 is different from the shape of the second region 120 of the orientation layer 103 of the laminated structure 100A shown in FIG. 5.

In the manufacturing method of the laminated structure 100B shown in FIG. 6, it is also possible to continuously form the orientation layer 103 on the amorphous substrate 101 having the insulating surface and the semiconductor layer 104 having a high degree of crystallinity and a c-axis orientation on the orientation layer 103, as explained in FIG. 1 and FIG. 2. When processing the semiconductor layer 104, it is preferable to etch the semiconductor layer 104 under conditions where the etching rate of the orientation layer 103 is low, as explained in FIG. 2. At this time, as shown in FIG. 6, undercuts may be formed in the orientation layer 103 relative to the semiconductor pattern 106.

The top surface 103b of the second region 120 of the orientation layer 103 is positioned lower than the top surface 103a of the first region 110. If the thickness of the second region 120 of the orientation layer 103 is 90% or less of the thickness of the first region 110 of the orientation layer 103, then the top surface 103b of the second region 120 is located below the top surface 103a of the first region 110. In other words, in the orientation layer 103, the thickness of the first region 110 is larger than the thickness of the second region 120. The difference between the orientation layer 103 of the laminated structure 100A and the orientation layer 103 is that the orientation layer 103 has an undercut at a predetermined depth from the top surface 103b of the second region 120 toward the semiconductor pattern 106. Specifically, the orientation layer 103 has a groove 103d in the second region 120 that extends from the lower end of the semiconductor pattern 106 toward the first region 110, and in a cross-sectional view, the groove 103d overlaps the semiconductor pattern 106.

As shown in FIG. 6, the top surface 103b of the second region 120 of the orientation layer 103 is positioned lower than the top surface 103a of the first region 110, and the orientation layer 103 has an undercut, so the surface area of the orientation layer 103 is increased compared to the laminated structure 100A shown in FIG. 5. Therefore, when forming a semiconductor device using the laminated structure 100B, the contact area with the film formed on the orientation layer 103 and the semiconductor pattern 106 can be increased. This improves the adhesion between the orientation layer 103 and the film formed on the semiconductor pattern 106.

As explained in Example 1, as shown in FIG. 6, etching can be performed until an undercut is formed in the orientation layer 103 with respect to the semiconductor pattern 106, thereby suppressing the generation of residue in the semiconductor layer 104.

### [Third Modification]

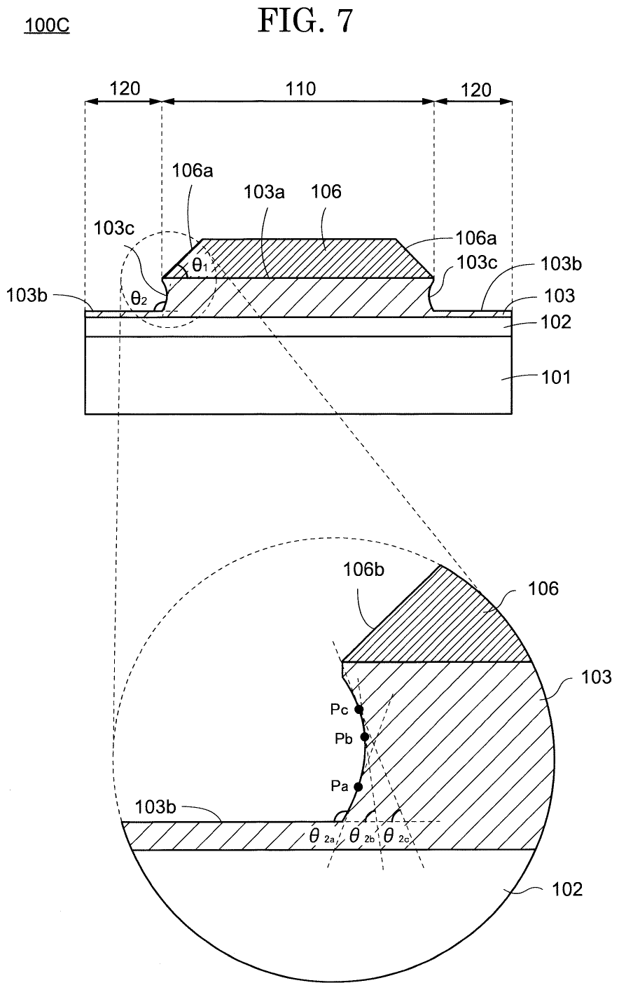

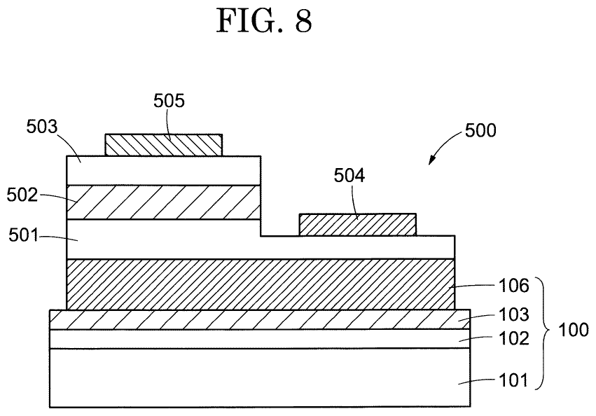

FIG. 7 is an end view of a laminated structure 100C that includes a semiconductor pattern containing gallium nitride in an embodiment of the present invention. The shape of the second region 120 of the orientation layer 103 of the laminated structure 100C shown in FIG. 7 is different from the shape of the second region 120 of the orientation layer 103 of the laminated structure 100.

As explained in FIG. 1 and FIG. 2, the method for manufacturing the laminated structure 100C shown in FIG. 7 also allows the continuous formation of an orientation layer 103 on the amorphous substrate 101 having the insulating surface and the semiconductor layer 104 having a high degree of crystallinity and a c-axis orientation on the orientation layer 103. When processing the semiconductor layer 104, it is preferable to etch the semiconductor layer 104 under conditions where the etching rate of the orientation layer 103 is low, as explained in FIG. 2. At this time, as shown in FIG. 7, the orientation layer 103 may be over-etched with respect to the semiconductor pattern 106.

The top surface 103b of the second region 120 of the orientation layer 103 is positioned lower than the top surface 103a of the first region 110. In other words, in the orientation layer 103, the thickness of the first region 110 is larger than the thickness of the second region 120. In this case, the thickness of the second region 120 is 50% or less of the thickness of the first region 110. Furthermore, the orientation layer 103 may be removed from the first region 110. In this case, the thickness of the second region 120 may be 0 nm. The difference between the orientation layer 103 of the laminated structure 100B shown in FIG. 6 and the orientation layer 103 is that the orientation layer 103 has the side surface 103c that is continuous with the top surface 103b of the second region 120 in the first region 110. The shape of side surface 103c is such that, in a cross-sectional view, the angle θ2 between the tangent of the side surface 103c and the top surface 103b of the second region 120 changes. The angle θ2 may change continuously or in stages.

FIG. 7 shows an enlarged view of part of the orientation layer 103 and the semiconductor pattern 106. The side surface 103c of the orientation layer 103 has a curved surface. When an arbitrary point Pa, Pb, or Pc is set on the side surface 103c, the angle between the tangent at the arbitrary point Pa and the top surface 103b of the second region 120 is θ2a. Also, the angle between the tangent at the arbitrary point Pb and the top surface 103b of the second region 120 is θ2b. Also, the angle between the tangent at the arbitrary point Pc and the top surface 103b of the second area is θ2c. In this way, the shape of the side surface 103c is such that the angle θ2 between the tangent of the side surface 103c and the top surface 103b of the second area 120 changes in cross-sectional view. The number of arbitrary points is not limited to three. Note that the shape in which the angle θ2 changes in stages refers to a shape in which the side surface 103c is not a curved surface but has steps.

As shown in FIG. 7, the top surface 103b of the second region 120 of the orientation layer 103 is positioned lower than the top surface 103a of the first region 110, and the orientation layer 103 has a side surface 103c that is continuous with the top surface 103b of the second region 120, so the surface area of the orientation layer 103 is increased compared to the laminated structure 100C shown in FIG. 7. Therefore, when forming a semiconductor device using the laminated structure 100C, the contact area with the film formed on the orientation layer 103 and the semiconductor pattern 106 can be increased. This improves the adhesion between the orientation layer 103 and the film formed on the semiconductor pattern 106.

As explained in the first and second modifications, as shown in FIG. 7, over-etching the orientation layer 103 with respect to the semiconductor pattern 106 can suppress the generation of residue in the semiconductor layer.

As explained in the first to third modifications, the orientation layer 103 and the semiconductor layer 104 formed on the orientation layer 103 can be selectively etched. This makes it possible to form the laminated structures 100A to 100C having a fine semiconductor pattern 106 on the orientation layer 103. Therefore, high-precision semiconductor devices can be formed using the laminated structures 100A-100C.

### Second Embodiment

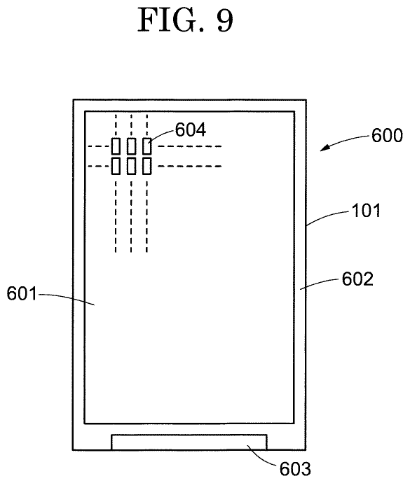

In the present embodiment, a semiconductor device 500 using the laminated structure 100 according to the first embodiment will be described with reference to FIG. 8 and FIG. 9.

FIG. 8 is an end view of a semiconductor device 500 that includes the laminated structure 100 of the first embodiment. Specifically, the semiconductor device 500 shown in FIG. 8 is an example of an LED element manufactured using the semiconductor pattern 106 shown in FIG. 4. In the drawings, the same symbols are used for the same elements as the laminated structure 100 shown in the first embodiment, and the same descriptions are omitted.

As shown in FIG. 8, the semiconductor device 500 includes the laminated structure 100 in the first embodiment, an n-type gallium nitride layer 501 arranged on the semiconductor pattern 106 of the laminated structure 100, an n-type electrode 504 arranged on the n-type gallium nitride layer 501, a light-emitting layer 502 spaced apart from the n-type electrode 504 and arranged on the n-type gallium nitride layer 501, a p-type gallium nitride layer 503 arranged on the light-emitting layer 502, and a p-type electrode 505 arranged on the p-type gallium nitride layer 503.

The semiconductor device 500 is formed by the process described below. After the semiconductor pattern 106 shown in FIG. 4 is formed, the n-type gallium nitride layer 501, the light-emitting layer 502, and the p-type gallium nitride layer 503 are sequentially grown on the semiconductor pattern 106. Thereafter, parts of the n-type gallium nitride layer 501, the light-emitting layer 502, and the p-type gallium nitride layer 503 are removed so that the n-type gallium nitride layer 501 is exposed. Finally, the n-type electrode 504 and the p-type electrode 505 are formed in contact with the n-type gallium nitride layer 501 and the p-type gallium nitride layer 503, respectively. With respect to the method for forming the n-type gallium nitride layer 501 and the p-type gallium nitride layer 503, the description of the n-type conductive semiconductor layer 104 and the p-type conductive semiconductor layer 104 in the first embodiment may be referred to.

Through the above process, the semiconductor device 500 shown in FIG. 8 is completed. The semiconductor device 500 of the present embodiment is formed using the highly crystalline semiconductor pattern 106 formed on the amorphous substrate 101. Therefore, according to the present embodiment, the semiconductor device 500 can be manufactured on the inexpensive amorphous substrate 101. In addition, since the semiconductor device 500 can be manufactured on the large-area amorphous substrate 101, productivity is improved. In addition, according to the present embodiment, since the highly crystalline gallium nitride layer can be formed by the sputtering method, the semiconductor device 500 can be manufactured with high throughput without being exposed to a high temperature throughout the entire process. Further, according to the present embodiment, a high-definition semiconductor device can be formed by using the laminated structure 100 having the fine semiconductor pattern 106.

The semiconductor device 500 shown in FIG. 8 is merely an example of an LED element and may be an LED element of another structure. For example, the light-emitting layer 502 may have a quantum-well structure in which the gallium nitride layer and the indium gallium nitride layer are alternately stacked.

In addition, although the example in which the semiconductor device 500 is manufactured using the laminated structure 100 has been described in the present embodiment, the semiconductor device 500 may be manufactured using the laminated structures 100A to 100C.

FIG. 9 is a plan view showing a light-emitting device 600 using the semiconductor device 500 including the laminated structure 100 according to the first embodiment. As shown in FIG. 9, a display unit 601 and a peripheral circuitry 602 are arranged on the amorphous substrate 101. A terminal 603 for inputting various signals (video signals and control signals) to the light-emitting device 600 is arranged in part of the peripheral circuitry 602. A plurality of pixels 604 is arranged in a matrix inside the display unit 601. The semiconductor device 500 shown in FIG. 8 is arranged in each pixel 604. Although not shown, a semiconductor chip for controlling light emission and non-light emission of the semiconductor device 500 may be arranged in each pixel 604.

### Third Embodiment

In the present embodiment, an example in which a semiconductor device is formed having a structure different from that of the second embodiment will be described. Specifically, in the present embodiment, an example in which a HEMT (High Electron Mobility Transistor) is formed as a semiconductor device will be described. In the drawing, the same elements as those of the laminated structure 100 shown in the first embodiment are denoted by the same reference signs, and redundant explanations are omitted.

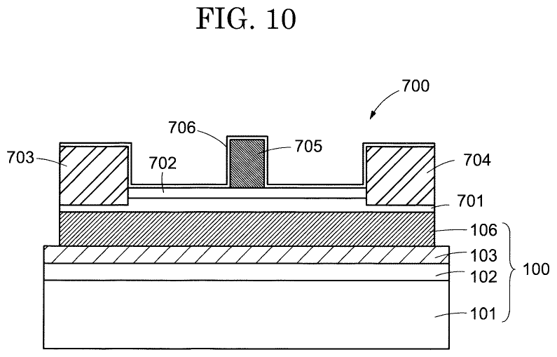

FIG. 10 is an end view showing a semiconductor device 700 including a gallium nitride-based semiconductor layer according to the fourth embodiment. Specifically, the semiconductor device 700 shown in FIG. 10 is an example of the HEMT manufactured using the semiconductor pattern 106 shown in FIG. 4 in the first embodiment.

As shown in FIG. 10, the semiconductor device 700 includes the laminated structure 100 in the first embodiment, an n-type aluminum gallium nitride layer 701 arranged on the semiconductor pattern of the laminated structure, an n-type gallium nitride layer 702 arranged on the n-type aluminum gallium nitride layer 701, a source electrode 703 arranged in contact with the n-type gallium nitride layer 702, a drain electrode 704 spaced apart from the source electrode 703 and in contact with the n-type aluminum gallium nitride layer 701, and a gate electrode 705 sandwiched between the source electrode 703 and the drain electrode 704 on the n-type aluminum gallium nitride layer 701. In the semiconductor device 700, silicon nitride may be arranged as a protective layer on the source electrode 703, the drain electrode 704, and the gate electrode 705.

The semiconductor device 700 is formed by the process described below. The n-type aluminum gallium nitride layer 701 and the n-type gallium nitride layer 702 are sequentially formed on the semiconductor pattern 106 made of the gallium nitride-based semiconductor layer. The sputtering method can be used to form these gallium nitride-based semiconductor layers. A trench reaching the n-type aluminum gallium nitride layer 701 is arranged in the n-type aluminum gallium nitride layer 701 and the n-type gallium nitride layer 702, and the source electrode 703 and the drain electrode 704 are arranged therein. The gate electrode 705 in contact with the n-type gallium nitride layer 702 is arranged between the source electrode 703 and the drain electrode 704. Finally, a silicon nitride layer 706 is formed as a protective layer, thereby completing the HEMT shown in FIG. 10.

The semiconductor device 700 of the present embodiment is formed using the highly crystalline gallium nitride layer (the semiconductor pattern 106) formed on the amorphous substrate 101. Therefore, according to the present embodiment, the semiconductor device 700 can be manufactured on the inexpensive amorphous substrate 101. In addition, since the semiconductor device 500 can be manufactured on the large-area amorphous substrate 101, productivity is improved. In addition, according to the present embodiment, since a plurality of gallium nitride-based semiconductor layers is formed by a sputtering method, the semiconductor device 700 can be manufactured with high throughput without being exposed to high temperature throughout the entire process. Furthermore, according to the present embodiment, a high-definition semiconductor device can be formed by using the laminated structure 100 having the fine semiconductor pattern 106. In addition, the semiconductor device 700 shown in FIG. 10 is merely an example of the HEMT, and may be the HEMT of another structure.

Each of the embodiments described above as an embodiment of the present invention can be appropriately combined and implemented as long as no contradiction is caused. The addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A multilayer structure comprising:
an amorphous substrate having an insulating surface;
an orientation layer on the amorphous substrate; and
a semiconductor pattern containing gallium nitride on the orientation layer,
wherein
the orientation layer has a first region overlapping the semiconductor pattern and a second region not overlapping the semiconductor pattern.

2. The multilayer structure according to claim 1, wherein
a top surface of the second region is positioned lower than a top surface of the first region.

3. The multilayer structure according to claim 2, wherein
the orientation layer has a groove in the second region that extends from a lower end of the semiconductor pattern to the first region, and in a plan view, the groove overlaps the semiconductor pattern.

4. The multilayer structure according to claim 1, wherein
the orientation layer has a side surface continuous with the top surface of the second region in the first region.

5. The multilayer structure according to claim 1, wherein
the orientation layer is composed of a conductive material or an insulating material having a c-axis orientation.

6. The multilayer structure according to claim 1, wherein
the amorphous substrate is an amorphous glass substrate or a resin substrate.

7. A method for producing a multilayer structure comprising:
forming an orientation layer on an amorphous substrate having an insulating surface;
depositing a semiconductor layer containing gallium nitride on the orientation layer; and
etching the semiconductor layer containing gallium nitride to form a semiconductor pattern on the top surface of the orientation layer, thereby forming a first region overlapping the semiconductor pattern on the orientation layer and a second region not overlapping the semiconductor pattern on the orientation layer.

8. The method according to claim 7, wherein
the semiconductor layer is etched so that the top surface of the second region in the orientation layer is positioned lower that the top surface of the first region.

9. The method according to claim 7, wherein
the semiconductor layer is etched so that the orientation layer has a groove in the second region that extends from a lower edge of the semiconductor pattern to the first region, and in a plan view, the groove is etched so that it overlaps the semiconductor pattern.

10. The method according to claim 7, wherein
the semiconductor layer is etched so that the orientation layer is etched to form a side surface continuous with the top surface of the second region in the first region.

11. The method according to claim 7, wherein
the orientation layer is composed of a conductive material or insulating material having the c-axis orientation.

12. The method according to claim 7, wherein
the amorphous substrate is an amorphous glass substrate or a resin substrate.

13. The method according to claim 7, wherein
the semiconductor layer containing gallium nitride is formed by a sputtering method.

14. A semiconductor device using the multilayer structure according to claim 1.
